(19) United States
(12) Patent Application Publication
(10) Pub. No.: US 2013/0193484 A1
(43) Pub. Date: Aug. 1, 2013

(54) FIELD-EFFECT TRANSISTOR ON A SELF-ASSEMBLED SEMICONDUCTOR WELL

(71) Applicants: Georgios Katsaros, Linz (AT); Silvano De Franceschi, Fontaine (FR)

(72) Inventors: Georgios Katsaros, Linz (AT); Silvano De Franceschi, Fontaine (FR)

(73) Assignee: COMMISSARIAT A L'ENERGIE ATOMIQUE ET AUX ENE ALT, Paris (FR)

(21) Appl. No.: 13/878,501

(22) PCT Filed: Oct. 6, 2011
(86) PCT No.: PCT/EP11/67504

§ 371 Date: Apr. 9, 2013

(30) Foreign Application Priority Data
Oct. 11, 2010 (FR) 10 58246

(51) Int. Cl. H01L 29/78; H01L 29/66; H01L 27/12

(52) U.S. Cl. CPC H01L 29/7839; H01L 27/1203; H01L 29/66643
USPC 257/192; 257/349; 438/164

(57) ABSTRACT

A device including at least one transistor on a substrate in a first semiconductor material, each transistor including a gate electrode as a gate, two conductor electrodes, an island in a second semiconductor material inlaid in the substrate, defining a region capable of forming a channel as a channel region, and an insulating layer separating the gate from the two electrodes and the channel region. The channel region is inside the island and is in direct electrical contact with at least one of the two conductor electrodes.

### TECHNICAL FIELD

The invention concerns the sphere of field effect transistors. Said transistors are commonly used in microelectronics to form logic or electronic components.

### STATE OF THE PRIOR ART

Transistors, through developing user needs, are destined to undergo improvement for the purpose of ever better performance.

A transistor formed in a semiconductor substrate comprises a gate on the surface of the substrate. The gate, without electric contact, covers a space called a channel region located between a source and a drain present in the substrate. In addition, a source electrode is in contact with the source and a drain electrode is in contact with the drain. The semiconductor substrate is doped with a first type of doping at a first dopant density. The source and the drain are formed by regions of the semiconductor substrate that are doped at much higher dopant densities than the first dopant density. Preferably the source and drain have opposite type of doping to the first type of doping.

Between the source and the drain, and hence located underneath the gate, the channel region is doped according to the first type of doping at the first dopant density. It is called a channel region since this region is used to form a conductive zone, called a channel, between the source and the drain when a given gate voltage is applied between the gate and the substrate. The source and the drain are spaced apart by a distance commonly called a gate width. The gate additionally is of given length measured over a plane of the surface of the substrate in a direction substantially perpendicular to the gate width.

Under certain conditions, depending on the gate voltage and gate width, the channel electrically connects the source and the drain. The circulation of carriers can then take place between the source electrode and the drain electrode.

At an electric contact between a metal electrode and a semiconductor material, a potential barrier is normally formed called a Schottky barrier. The Schottky barrier limits a capacity of the carriers to move between the electrode and the semiconductor material. Yet, one of the important characteristics of a transistor is to allow efficient injection of carriers.

It is to overcome this problem that the source and the drain are formed by highly doped regions inserted in the semiconductor material of the substrate. Doping allows an increase in the quantity of charge carriers in the semiconductor material, elimination of the Schottky barrier and a reduction in the contact resistance between the source and drain electrodes and the corresponding highly doped regions. Therefore, a highly doped source and drain are used and a channel region that is less highly doped between the source and the drain. This gives rise respectively to low Schottky barriers between the source electrode and the source, between the drain electrode and the drain and between the drain or source and the channel region. Low Schottky barriers can therefore be obtained of the order of a few kiloohms to a few tens of kiloohms. This is generally acceptable for transistors using microelectronic or nanoelectronic technology.

To increase the performance level of transistors, with each technological generation the gate widths of the transistors are reduced compared with a prior technological generation. A shorter gate width leads to a shorter switching time.

The substrate comprises a mean dopant density, representing a number of dopants per unit volume. The dopants are distributed in the substrate statistically and not strictly homogeneously. When the length and width of the gate are reduced down to a few tens of nanometers, the mean density is no longer representative of the number of dopants contained in a given channel region. If the substrate is cut into several examined volumes, there will be a given standard deviation for the dopant density in the said volumes, compared with the mean density. The smaller the examined volumes, the greater the standard deviation, some of volumes having a higher dopant density than the mean density and other volumes having a dopant density lower than the said mean density.

When said volumes are of very small size, the standard deviation can be such that at least one substrate volume has a dopant density 2 times, 5 times, 10 times greater than another volume of the substrate, or even greater.

Here is an example to illustrate the foregoing assertion:

if there is only one volume in the substrate, the volume has the mean dopant density;

if there are numerous volumes in the substrate, forming atomic meshes having sides of two or three atoms, numerous volumes do not have any dopant i.e. zero density. In parallel, other volumes have one dopant atom or two dopant atoms dispersed in these volumes comprising a few atoms of the substrate. These latter volumes then have a much higher dopant density than the mean density.

Therefore, when the gate dimensions are small, the channel regions have dimensions close to those of the above-described small volumes. Therefore, the standard deviation of the density of dopant atoms between neighbouring channel regions becomes high. Some channel regions may have much more dopant than other channel regions. This may give rise to the onset of major variations in performance level between channel regions of two neighbouring transistors. This can particularly be verified for gate dimensions of the order of a few nanometres or a few 10 nm to 20 nm, i.e. a few tens of atoms.

This reasoning remains valid if the gate length is close to 30 nm or 40 nm. The standard deviations are smaller than in the preceding case and there is less variation in dopant density from one channel region to another. However, here again, some channel regions may have more dopants than other channel regions included in other transistors. This also leads to a variation in performance level between the transistors formed on one same substrate.

The use of dopants when the gate is of small size therefore gives rise to variations in performance from one transistor to another. This reduces the manufacturing repeatability of transistors and reduces the reliability of said transistors.

The source and the drain are generally formed by localised implanting of dopants followed by the diffusion of these dopants during an annealing operation. This gives rise to a second problem.

The diffusion of the dopants in a single-crystal is also a statistical phenomenon and the aforementioned influence of the small dimensions of a transistor on the standard deviation of dopant density is also found during this annealing. Therefore, here again, the small dimensions of the gate are found to have an influence.

In standard microelectronic transistors, having gates of width greater than 25 nm or 50 nm or 100 nm, during diffusion some dopant atoms may diffuse randomly further than others, as far as the channel region. This leads to a local addition of a few dopant atoms in the channel region. Given the dimensions of the channel region, it has a dopant density close to the mean density and the adding of a few dopant atoms does not fundamentally modify the dopant density.

However, when the gate dimensions are sufficiently small, the channel regions have very small volumes. The evaluating of the number of atoms in each channel region amounts to sampling the substrate using very small volumes.

From one channel region to another there is therefore a standard deviation in the number of dopants which is high. In addition, each dopant atom present in the channel region has a strong influence on the dopant density in the said channel region. If, during diffusion by annealing, some dopant atoms from the source or drain diffuse into the channel region of a transistor, they will strongly modify the dopant density in the said channel region. The channel region then has a dopant and charge carrier density that is substantially increased compared with its initial dopant density.

Therefore, the use of dopants to form the source and drain remains a step which may lead to variations in performance from one transistor to another. This may therefore reduce the fabrication repeatability of the transistors and reduce the reliability thereof.

In addition, since annealing operations contribute towards causing the dopants to diffuse beyond an initial diffusion profile, the use of additional annealing operations is limited for any other step following after the dopant diffusion step. If these annealing operations are not limited, there is a risk that some dopants present in the substrate to form the source and drain will diffuse, drawing the source and drain close to one another. Said mechanism being statistical, this diffusion is not homogeneous from one transistor to another. It cannot therefore be easily controlled. Some transistors will therefore have their gate width reduced more than other neighbouring transistors.

This problem, and others, is known to persons skilled in the art and some are cited in the document <<Vers la monoélectronique>> by Jacques Gautier, simultaneously published in September 1999 in the periodical <<Signaux>>, Number 94 and in <<Revue de l'électricité et de l'électronique, REE>>, Number 9.

Finally, there is a further problem. When reducing the dimensions of a transistor, the source and drain electrodes are of smaller size than in the preceding technological generation. This leads to having increased contact resistances for same dopant concentrations compared with the preceding technological generation.

Finally, the annealing operations needed to cause the dopants to diffuse lead to a strong heat budget. On this account, they may be harmful for applications in which structures already exist that are sensitive to the heat budget prior to the forming of the transistors.

### DISCLOSURE OF THE INVENTION

The objective of the invention is to overcome the problems originating from a statistical presence of dopants in a transistor formed on a semiconductor substrate, whilst maintaining low contact resistance.

The invention therefore first concerns a device having at least one transistor on a substrate in a first semiconductor material. Each transistor comprises a gate electrode, called a gate, two conductor electrodes called source electrode and drain electrode, an island in a second semiconductor material and an insulating layer separating the gate from the two electrodes and the island. The island is inlaid in the substrate and defines a region capable of forming a channel, called a channel region. The device according to the invention is characterized in that the channel region lies inside the island and is in direct electrical contact with the two conductor electrodes.

In this manner, for at least one of the electrodes, there is no doped region such as source or drain, between the electrode and the channel region formed by the island. Electrons are able to circulate from the electrode as far as the channel region via tunnel effect.

Advantageously, the channel region is in direct electrical contact on one side with one of the two conductor electrodes, called the source electrode, and on the other side it is in direct electrical contact with the other of the two conductor electrodes called the drain electrode. Since it is directly connected to two separate electrodes, the island allows a transistor of small dimensions to be formed that does not require the use of highly doped source and drain zones. Therefore according to the invention there is no risk of creating variable doping from one transistor to another in the channel region.

Preferably, the conductor electrodes are in metal of aluminium or platinum type. In addition, it is preferable that the first semiconductor material should be silicon and the second semiconductor material should be Si₁₋ₓGeₓ, x being between 0 and 1. It has effectively been observed that the combined use of aluminium and a channel region in Si₁₋ₓGeₓ (SiGe) allows conduction via tunnel effect between an electrode and the channel region that is suitable for a transistor. Other materials however can be used. Charge carriers are also able to circulate in SiGe with reasonable resistance without it being necessary to impose a high gate voltage. Therefore, if conductions via tunnel effect take place between one electrode and the channel region, and between the channel region and the other electrode, the charge carriers are able to circulate from one electrode to the other.

The channel region is included in a SiGe island, inlaid on the surface of a substrate in silicon. The charge carriers cannot circulate freely, with low resistance, in the weakly or scarcely doped silicon without an artificial accumulation of carriers in the silicon. Such artificial accumulation is obtained in the prior art by imposing a high voltage between the gate and the silicon substrate, which forms a conductive channel in the silicon. In the invention, the channel is formed, even with a low gate voltage, in the island in SiGe. Since there is no artificial accumulation of carriers in the silicon of the substrate, there is no or only little circulation of carriers from the islands towards the silicon substrate. This therefore makes it possible substantially to isolate the transistor of one island from the transistors of other neighbouring islands In particular, there is greater insulation between different transistors than if the substrate were entirely composed of the second semiconductor material, here SiGe.

The island may have a height, measured in a direction perpendicular to a main surface of the substrate, of between 1 nm and 60 nm. It is also possible to form an island having a mean diameter, or width, measured over a plane substantially parallel to a main surface of the substrate, of between 10 nm and 400 nm. The islands thus formed are of small size. The channel region being limited to the island, the channel regions present in the core of the transistors are contained within the island thereby limiting any possible current leakage.

The substrate is advantageously of semiconductor-on-insulator type, in this case silicon-on-insulator (SOI). This makes it possible both to obtain a surface layer of very good quality and to reduce leakage currents, as is known to those skilled in the art.

A device according to the invention may comprise several transistors. It may then be advantageous to have a trench in the substrate to electrically insulate at least two neighbouring transistors. This trench can be filled with insulating material e.g. SiO2. It may completely surround each transistor. Finally, the trench can be extended depth-wise if the substrate is in SOI with a buried insulating layer, as far as said buried insulating layer.

In some cases, the substrate carrying the transistors is an upper layer in semiconductor material present on a flexible substrate. Said upper layer may have a thickness equal to or less than about 10 nm or 5 nm or 3 nm or 2 nm.

The invention also concerns a method for fabricating a device having at least one transistor according to the invention. Said method comprises at least the following successive steps:

a) forming one or more holes having a given depth and width hollowed in the surface of a substrate in a first semiconductor material;

b) forming an island in a second semiconductor material in each hole;

c) forming on each island at least one first conductor electrode in direct electrical contact with the island;

d) forming at least one second conductor electrode per island which may or may not be in direct electrical contact with the island;

e) depositing an electrically insulating layer on the surface of the substrate, above each island and each conductor electrode;

f) depositing a conductor layer above the island, separated from the island and the conductor electrodes by the insulating layer, and forming a gate electrode.

The forming of the second electrode may be performed simultaneously with the step to form the first electrode. The second electrode is then preferably in direct electrical contact with the island.

Step b) is advantageously preceded by a step to deposit a thin layer of single-crystal silicon, called a treatment layer. The holes formed at step a) lead to a given topology and the treatment layer lines the holes and creates a new surface having substantially the same topology as the one formed at step a). However, said treatment layer may have a thickness on the sidewalls of the holes formed at step a) that is narrower than at the bottom of the holes, thereby forming an attenuation of the initial topology of the holes. The hole forming step may comprise etching which creates interface defects on the surface of the hole. The treatment layer then masks these defects and allows a new defect-free surface to be obtained.

In one method according to the invention, step b) to form islands may comprise the depositing of one or more monolayers of germanium forming a silicon-germanium island in each hole. The silicon-germanium islands are formed by concentrating and agglomerating the germanium monolayers in the holes. Simultaneously, silicon is diffused in said germanium islands in the progress of being formed, and this allows a Si₁₋ₓGeₓ island to be formed in each hole.

Advantageously, the depositing of germanium monolayers is followed by the depositing of a capping layer, advantageously in single-crystal silicon, covering the silicon-germanium islands. It is possible to form a trench between at least two neighbouring transistors so as partly to insulate the two neighbouring transistors, the trench being devoid of any solid material or filled with an insulating material.

Further advantageously, the substrate may be the surface layer in semiconductor material, comprising the surface in which the holes are hollowed, of a substrate of semiconductor-on-insulator type called an SOI substrate. The said surface layer is separated from the said SOI substrate and bonded to a substrate in polymer of so-called <<flexible substrate>> type, prior to steps a) or c) or after step f).

### BRIEF DESCRIPTION OF THE DRAWINGS

The invention will be better understood and other details, advantages and characteristic thereof will become apparent on reading the following description given as a non-limiting example and with reference to the appended drawings in which:

FIG. 1 illustrates a device according to the invention having a single transistor;

FIG. 2 illustrates a device according to the invention with at least three transistors separated by trenches;

FIGS. 3A to 3F schematise a method according to the invention for forming islands;

FIGS. 4A to 4D illustrate details of the forming of an island according to the invention;

FIGS. 5A to 5C give a cross-sectional view of different shapes of islands;

FIGS. 6A to 6D illustrate a method according to the invention allowing a device according to the invention to be formed from an island;

FIGS. 7A to 7C illustrate various steps for forming a floating substrate and the bonding thereof onto a flexible substrate;

FIGS. 8A and 8B illustrate the fabrication of transistors according to the invention and the bonding thereof onto a flexible substrate;

FIGS. 9A to 9C illustrate the bonding of a floating substrate onto a flexible substrate and the fabrication of transistors according to the invention on the said bonded floating substrate.

Identical, similar or equivalent parts in the different Figures carry the same reference numbers to facilitate cross-reading between the Figures.

The different parts illustrated in the Figures are not necessarily drawn to uniform scale for better legibility of the Figures.

The Figures illustrating different embodiments of the device of the invention are given as examples and are non-limiting.

### DETAILED DESCRIPTION OF PARTICULAR EMBODIMENTS

The invention first concerns a transistor in which a source electrode and/or drain electrode are in direct contact with a region in semiconductor material forming a channel between the source and the drain. According to the invention, the contact resistance of this assembly is sufficiently low to allow acceptable functioning of the said transistor.

Secondly, the invention pertains to a device comprising a said transistor. In the remainder of the description, the transistor will not be considered alone but will be considered to be included in a device according to the invention except when an isolated transistor is expressly discussed.

Finally, a preferred method will be described allowing a transistor according to the invention to be produced.

At the time of contact between a metal electrode and a semiconductor material, there is generally very high access resistance due to the Schottky barrier, for example having a value of several megaohms. This is why transistors are fabricated so as to comprise two intermediate zones between the source and drain electrodes and the channel region, respectively <<source>> and <<drain>> and formed of region in highly doped semiconductor material.

The invention proposes dispensing with the source and drain to avoid problems which occur when forming doped zones of small size and those problems reducing their performance level as previously mentioned.

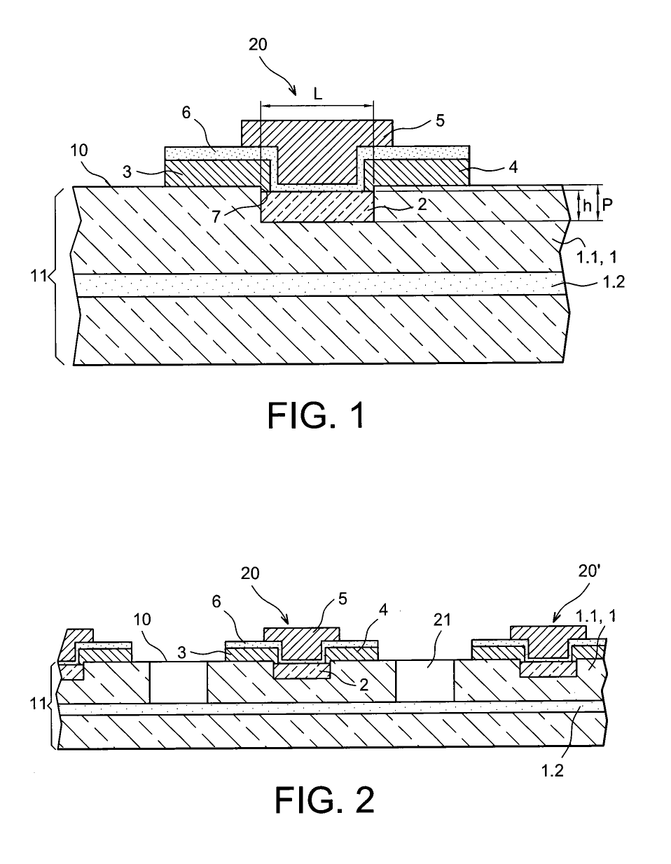

A device according to the invention is illustrated in FIG. 1.

The device of the invention is prepared on a substrate 1, possibly and preferably being a surface layer 1.1 of a substrate 11 of <<semiconductor-on-insulator>> type or preferably of <<silicon-on-insulator>> type (SOI). The said substrate 1 has a main surface 10 including at least one transistor 20; the main surface 10 is in a first semiconductor material, preferably silicon. A substrate of SOI type comprises a surface layer 1.1 composed of the first semiconductor material, separated by a layer in insulating material 1.2 of a main substrate 1.3 in semiconductor material, imparting mechanical strength to the SOI substrate. The surface layer 1.1 is preferably of narrow thickness, for example less than about 100 nm or than about 50 nm, or less than 20 nm or close to 1 nm. The narrower the thickness of the surface layer 1.1 the more the transistor 20 will have high parallel resistance. This means that the residual current between the source and the drain in the off-state of the transistor will be favourably weakened and there will be fewer leakage currents between two neighbouring transistors.

The transistor 20 comprises an island 2 in a second type of semiconductor material, a source electrode 3 and a drain electrode 4. The island 2 is preferably inlaid in the main surface 10 of the substrate 1.

The island 2 is in direct electrical contact via one edge with at least the source electrode 3. Preferably, the island 2 is additionally in direct electrical contact with the drain electrode 4. The island 2 is preferably in SiGe. The electrodes 3 and 4 may be metallic and advantageously in aluminium or another metal or metal alloy.

In the remainder of the description, it will be considered, if not specified, that the substrate 1, i.e. the surface layer 1.1 of the substrate of SOI type 11, is in silicon, that the island 2 is in SiGe and that the source electrode 3 and drain electrode 4 are in aluminium. However, other materials can be used to form a transistor included in a device according to the invention such as described further on.

The island 2 and the aforementioned two electrodes 3, 4 are separated by a gate electrode called a gate 5, by an insulating layer 6, electrically insulating, also called a gate oxide. In the remainder of the description, when mention is made of two electrodes this will designate the source electrode 3 and drain electrode 4 and will not designate the gate electrode 5. The latter will be solely referred to as the <<gate 5>>.

The gate 5 extends opposite every point of the substrate 1 present between the source electrode 3 and the drain electrode 4, and in particular opposite every point of the island 2 present between the two electrodes 3, 4. This part of the island 2, lying between the two electrodes 3, 4, forms a channel region. For simplification, it will be considered in the remainder of the description that the entire island 2 forms the channel region.

In operation, it is possible to impose a difference in potential between the gate 5 and the electrodes 3 et 4. This gives rise to a high voltage gradient in the channel region, which can lead to an accumulation of carriers in the island 2 and thereby form a conductive channel in the island 2 between the source electrode 3 and the drain electrode 4.

The channel of the transistor 20 is formed in the island 2 and not in the substrate 1. It is therefore not necessary to seek any particular doping in the substrate 1. Therefore the substrate 1, or the surface layer 1.1 if a substrate 11 of SOI type is used, can be devoid of any doping. Said non-doping allows simplified fabrication of the substrate 1. In addition, no statistical effect due to doping of the substrate 1 can have an influence on the performance of the transistor 20 when transistors of small size are to be produced.

The island 2 is preferably located in a hole 7 defined in the main surface 10, which has the function of controlling the position thereof on the substrate by promoting nucleation of the island. The island 2 formed by epitaxial growth is inlaid in the surface of the substrate and can be partly or entirely contained within the hole. Its dimensions and shape are controlled by the growth parameters and not by the size of the hole. The island may have a width L and length in the hole 7 of between about 15 nm and about 100 nm, preferably between 15 nm and 40 nm. These two dimensions are measured substantially parallel to the main surface 10. The hole 7 may be circular. In this case, the island 2 is then also circular as seen from overhead and has a diameter of between 15 nm and about 100 nm, advantageously between 15 nm and 40 nm.

In some cases, the hole 7 may be a trench. The trench is then filled with aligned islands, close to one another but most of which are not in direct contact with the other islands.

The hole 7 has a bottom located at a depth P of between about 5 nm and about 50 nm relative to the main surface 10 of the substrate 1. The island 2 may have a height h less than, equal to or higher than the depth P of the hole.

Therefore, depending on how persons skilled in the art wish to apply the invention to a given transistor for a particular application, the height h of the island 2 may vary between about 1 nm and about 60 nm. The island has a form factor i.e. a ratio between its height h and it base diameter or base width L of between 0.05 and 0.3.

As stated above, if the first semiconductor material is in silicon, the island 2 is preferably in silicon-germanium (SiGe) or in material of type SixGe1₋ₓhereinafter called SiGe. SiGe is able to be formed on top of a substrate in silicon using epitaxial growth following the crystalline lattice of the silicon. It is therefore possible to form single-crystal SiGe at least locally on a silicon substrate. This property of SiGe is of importance for implementing the invention.

The two electrodes 3, 4 are each separated from the island 2 in SiGe by a potential barrier causing a given access resistance.

In the invention, the potential barrier between the island 2 and the electrodes 3, 4 is easily overcome by charge carriers, electrons or holes, via tunnel effect. The transistor is then subjected to relatively weak access resistance, typically of the order of a few 10 kiloohms, but which may only be a few kiloohms.

The second semiconductor material forming the island 2 has a valence band of which the top has a given energy level.

Each of the two electrodes 3, 4 has a Fermi level.

It will be said that the Fermi level of one of the two electrodes 3, 4 and the top of the valence band of the island 2 are aligned if the Fermi level of the said electrode and the energy level at the top of the valence band have a negligible difference. This is the case whether the Fermi level of the electrode 3, 4 is higher than, lower than or equal to the energy level of the valence band. If the top of the valence band of the island 2 is aligned with the Fermi level of one of the two electrodes 3, 4, conduction is able to occur via tunnel effect between the island 2 and the said electrode 3, 4.

In addition, when the Fermi level in one of the electrodes 3, 4 has a value less than the energy level of the top of the valence band of the island 2, conduction may also occur via tunnel effect from the said electrode 3, 4 towards the island 2.

Conversely, if the top of the valence band of the island 2 has an energy level lower than the Fermi level in the other of the two electrodes 3, 4, conduction may occur via tunnel effect from the island 2 towards the other of the two electrodes 3, 4.

If the energy level at the top of the valence band of the island 2 is between the Fermi levels of the electrodes 3 and 4 or is aligned with one thereof, circulation of carriers may occur between the electrode having the highest Fermi level and the electrode having the lowest Fermi level, across the island 2. If the carriers are electrons, they move from the highest Fermi level towards the lowest. If the carriers are holes, they move in reverse direction.

If the Fermi levels in the source and drain electrodes are both higher or both lower than the energy level of the valence band of the island, there is no possible circulation of carriers. The Fermi levels of the two electrodes 3, 4 can be modified if a given polarization voltage is applied between the said electrodes. One thereof will then have its Fermi level reduced whilst the other will increase its Fermi level. In the presence of a polarization voltage between the electrodes 3, 4, it is therefore possible for the valence band of the island 2 to reach a level that is between the Fermi levels of the two electrodes. Nonetheless, in numerous situations the difference in potential used must be very high.

In the invention however, in addition to this modulation of the Fermi levels of the two electrodes 3, 4, it is possible to add a modulation of the energy level at the top of the valence band of the island 2, additionally controlled by the potential of the gate 5. This allows modulation of the current through the effect of the gate itself 5. By applying a voltage between the gate 5 and the substrate 1, it is possible locally to increase the carrier density in the island 2, thereby modifying the energy level at the top of the valence band of the island 2.

Therefore, by controlling the quantity of carriers in the island 2 and by imposing a given potential difference between the two electrodes 3, 4, it is easy to position the top of the valence band of the island 2 at an energy level between the Fermi levels of the two electrodes 3, 4. Conduction can then take place via tunnel effect between the two electrodes 3, 4.

Conversely, when the island 2 is emptied of its carriers by the voltage of the gate 5, the energy level at the top of the valence band of the island 2 lies removed from the Fermi levels of the two electrodes 3 and 4. No current is then able to circulate through the island 2 between the two electrodes 3, 4. Thus a said device with three terminals forms a novel type of transistor.

When the island 2 is in SiGe and the two electrodes 3, 4 are in aluminium, not only is the potential barrier sufficiently narrow to allow a tunnel effect, but there is also solely the need for low polarization between the electrodes 3, 4 to position the top of the valence band of the island 2 between the Fermi levels of the two electrodes 3, 4 or to align it with the Fermi level of at least one of the two electrodes 3, 4. Therefore only low polarization is needed to cause carriers to circulate between the two electrodes 3, 4 through the island 2.

As a variant, it is possible to use as alternate materials GaAs with InGaAs for the islands—or a substrate of GeOI type (germanium on insulator) with islands in InAs or InGaAS. The principle would then be the same as for the examples described here, but the carriers are conveyed by the conduction band. There would then only be conduction via tunnel effect if the bottom of the conduction band of the islands in InAs or InGaAs is positioned between the Fermi levels of the electrodes 3, 4. In other words, said transistors would be transistors of n type whereas islands in SiGe on a silicon substrate can be used for p-type transistors.

The island 2 may have different shapes as seen along a plane substantially perpendicular to the main surface 10, such has described below when discussing the method.

The access resistance of a transistor according to the invention being related to a sufficiently low <<tunnel>> resistance and not to a Schottky barrier, there is no need to form highly doped regions of source and drain type to obtain acceptable access resistance. It is not necessary either for the channel region to be doped. The island 2 is preferably non-doped. Therefore when fabricating the island 2, it is not necessary to add a dopant or to use annealing operations to cause the said dopant to diffuse. In addition, in a device composed of several transistors, no statistical variation occurs between two transistors related to local variations in dopant density in the channel regions.

The electrodes 3, 4 are preferably in aluminium or other metal or metal alloy such as copper, titanium, tungsten, gold, platinum . . . .

The gate 5 may be in any material usually used in microelectronics and nanoelectronics to form gate electrodes. In particular, the gate 5 may be in aluminium, copper, tungsten, platinum, polysilicon etc.

As stated previously, the gate 5 extends at least opposite every part of the island 2 lying between the two electrodes 3, 4. In some cases, the gate 5 may be superimposed over part of the source electrode 3 and/or drain electrode 4. The gate 5 is separated at every point from the two electrodes 3, 4 and the island 2 by the insulating layer 6. In this manner, when a gate voltage is applied to the gate 5, an electric field is produced at every point of the island 2 lying between the two electrodes 3, 4.

Depending on the polarity of the gate voltage, the electric field—in the region of the island close to the interface between the insulating layer 6 and the island 2—leads either to a zone enriched with carriers or to a zone depleted of carriers between the two electrodes 3, 4. If a carrier-rich zone is formed, this is likened to a conductive channel, of low resistance between the two electrodes 3, 4. Circulation of carriers can then easily take place between the two electrodes. The transistor 20 is then in the conducting state. As stated previously, the carrier density also has an influence on the energy level at the top of the valence band of the island 2 and hence on conduction via tunnel effect between the electrodes 3, 4 and the island 2.

Conversely, when a zone depleted of carriers is formed between the two electrodes 3, 4, the island 2 acts as a high resistance between the two electrodes 3, 4. Conduction is then no longer possible between the two electrodes 3, 4. The transistor 20 is then in the off-state.

When there is no potential difference imposed by the gate 5, the island 2 is likened to a resistance of high value separating the two electrodes. Then, depending on the potential difference between the source electrode 3 and the drain electrode 4, a very weak current is able to circulate as per the aforementioned mechanism of tunnel conduction effect, by movement of the carriers between each of the two electrodes and the channel region.

The insulating layer 6 is advantageously an oxide layer e.g. silicon oxide, but may be in any other material used in microelectronics as gate oxide of a transistor. The insulating layer 6 has a thickness and permittivity such that there is no notable tunnel current between the gate 5 and any one of the elements from among the source electrode 3, drain electrode 4 and the channel region formed in the island 2 between the two aforementioned electrodes. In general, if the insulating layer 6 is in silicon oxide SiO₂, it may have a thickness of between a few nm and 15 nm, for example 8 nm or 10 nm. Alternatively, it may be in HfO₂ or Al₂O₃ or any other oxide known in microelectronics.

In particular, the use of an oxide with high dielectric constant, e.g. higher than 5 or 10, such as hafnium oxide HfO, offers better capacitive coupling between the gate 5 and the channel region formed in the island 2. Said oxide can be deposited using different techniques, preferably the technique known as atomic layer deposition (ALD), and the thickness may be between a few nm and 15 nm e.g. 6 nm.

The invention also concerns a device comprising several transistors 20, 20′ similar to the one in FIG. 1. One particular embodiment of said device is partly illustrated in cross-section in FIG. 2.

This Figure shows two neighbouring transistors 20, 20′ on a substrate 1. The said substrate 1 in this example is a surface layer 1.1 of a substrate 11 of SOI type, semiconductor-on-insulator, comprising a buried oxide layer 1.2 underneath the surface layer 1.1. In this embodiment, the two transistors 20, 20′ may be separated from each other by a trench 21, cut in the surface layer 1.1.

Advantageously, each transistor 20, 20′ can be surrounded by a trench 21.

The trench 21 may fully cross through the surface layer 1.1 of the SOI-type substrate 11. Advantageously, the trench 21 exposes the buried oxide layer 1.2.

The trench 21 may be devoid of solid material or may be filled with an insulating material e.g. silicon oxide.

Such trench 21 allows one transistor 20 to be electrically insulated from any neighbouring transistor 20′ and reciprocally. It is thus possible to limit or eliminate any leakage current between the different transistors 20, 20′. If there are more than two transistors 20, 20′, they are then preferably separated from each other by at least one trench 21.

In some cases, the trench 21 may take up a minimum volume, sufficient to separate the transistors 20, 20′, but without taking up more volume than is necessary. In other cases, every part of the surface layer 1.1 which comprises neither island 2, nor source electrode 3 nor drain electrode 4, is removed and forms the trench 21. Any intermediate situation between the two aforementioned cases is possible.

The invention also concerns a method for fabricating a transistor according to the invention, or a device comprising one or more transistors according to the invention. Said method is performed in two parts:

First, it is necessary to fabricate islands which will be used to form channel regions for the transistors.

Next, the transistor(s) are fabricated from the said islands.

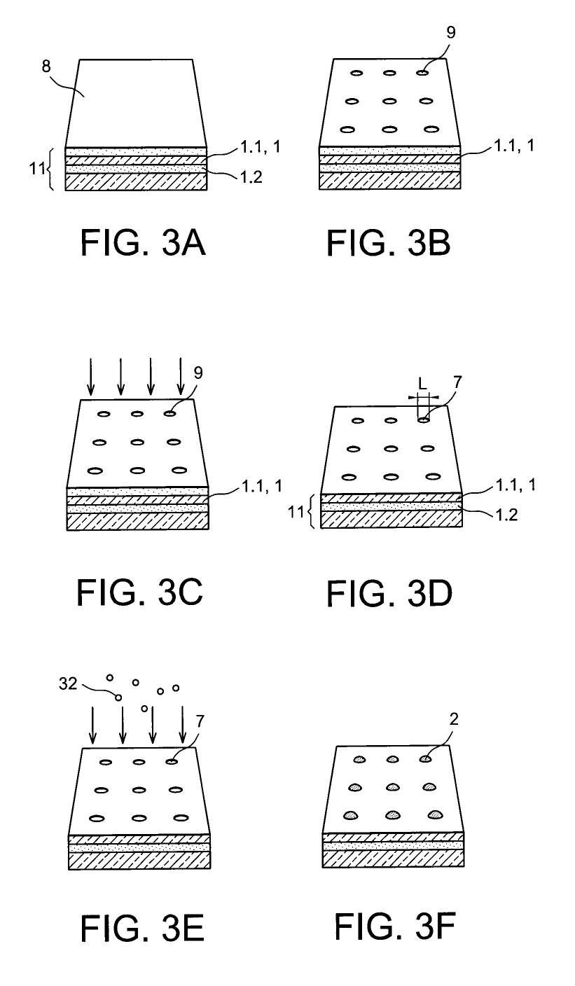

A method for fabricating islands in SiGe is described in FIGS. 3A to 3F.

A substrate 11 of SOI type is chosen, comprising a surface layer 1.1 on top of a buried oxide layer 1.2. The thickness of the surface layer 1.1 is chosen in relation to the desired application for the future transistors. On the said surface layer 1.1, a layer of resin 8 is deposited 8 (FIG. 3A).

Using lithography, spaces 9 are then released in the resin 8 so as locally to expose the surface layer 1.1 (FIG. 3B). Said spaces 9 are formed at every point where it is desired to produce an island, which will be used to form the channel region of a transistor according to the invention.

The lithography used may be standard photolithography used in microelectronics, e.g. photolithography specific to the forming of nanometric structures, or e-beam lithography. Alternatively, it may be nano-imprint lithography.

Subsequently, using reactive ion etching or any other type of acceptable etching, the surface layer 1.1 is etched at the spaces 9 (FIG. 3C). Therefore, as illustrated in FIG. 3D, after removing the resin there are holes 7 in the surface layer 1.1.

As mentioned previously in the description of the transistor, said holes have a depth of between about 5 nm and about 50 nm and a diameter, or at least a width L and/or length of between about 15 nm and about 100 nm, preferably between about 15 nm and about 40 nm.

The holes 7 can be positioned regularly and homogeneously on the surface of the substrate 1 formed by the surface layer 1.1. They may be circular or polygonal. Alternatively they may form trenches, each extending at the point where several transistors are planned to be positioned. In this case, several transistors may be formed on one same SiGe assembly.

The substrate 1 comprising the holes 7 is then subjected to a beam of germanium atoms 32 (FIG. 3E) under conditions allowing molecular beam epitaxy of germanium monolayers. Islands 2 in SiGe are then formed through a mechanism known as the Stranski-Krastanov mechanism, at a temperature of between about 250° C. and 800° C. (FIG. 3F). Alternatively, the depositing of germanium atoms may use chemical vapour deposition CVD or plasma-enhanced chemical vapour deposition PE-CVD.

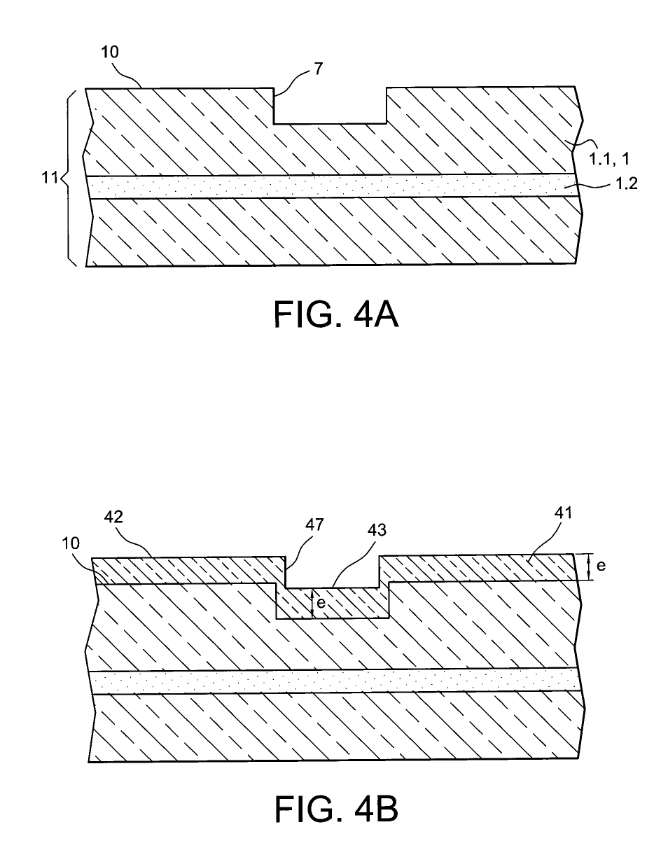

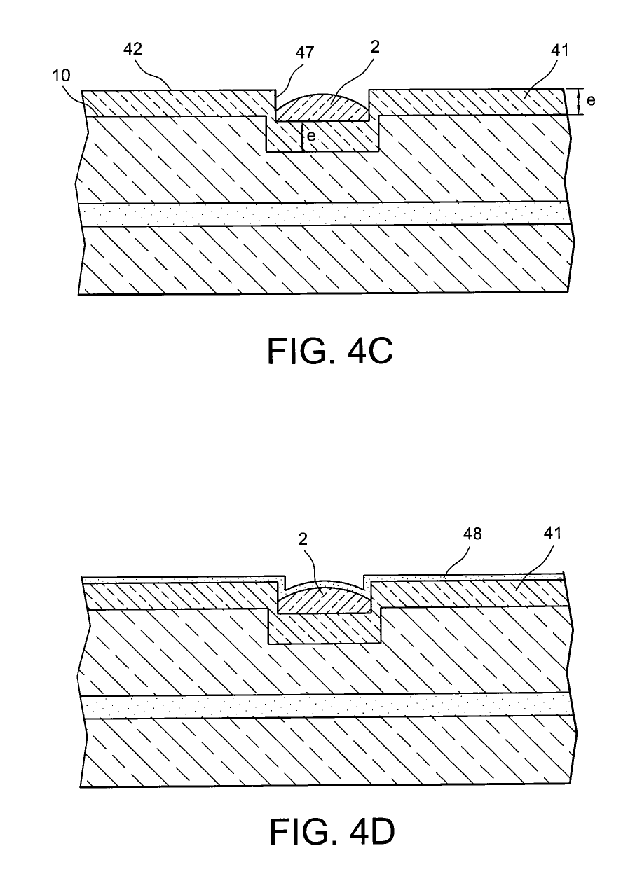

The germanium, via a variation in surface tension at the holes 7 to minimise its energy, has preference deposition in the holes 7. The germanium monolayers agglomerate in the holes 7 and this causes growth of germanium islands 2′. Silicon derived from the surface layer 1.1 diffuses in the germanium islands 2′ during their formation leading to the generation of islands 2 in SiGe. This diffusion takes place during the growth of the germanium islands 2′. Preferably, as illustrated in FIGS. 4A to 4C, a treatment layer 41 in single-crystal silicon is deposited after the formation of the holes 7 and before the formation of the germanium islands 2′, i.e. before the formation of the islands 2 in Si₁₋ₓGeₓ. FIG. 4A gives a cross-section of a structure such as the one shown in FIG. 3B. It illustrates a substrate 11 of SOI type comprising a surface layer 1.1 and a buried oxide layer 1.2. The surface layer 1.1 has a main surface 10 which is interrupted by at least one hole 7.

At a following step, a treatment layer 41 composed of the first semiconductor material i.e. the material of the surface layer 1.1 of the substrate 11 of SOI type, in this case silicon, is deposited on the main surface 10 and in the hole 7 (FIG. 4B). This treatment layer 41 lines the bottom and the walls of the initial holes. It has a thickness e possibly of between a few nanometres, one or two atomic monolayers and several hundred nanometres at the bottom of the initial holes. The reactive ion etching used to form the holes 7 hereinafter called the initial holes, generally produces defects at every etched point, here at the bottom of the initial holes 7. The treatment layer 41 is used to cause these defects to disappear. Since the treatment layer 41 lines the initial holes 7, it will be understood that a new surface 42 is created on top of the main surface 10. In addition a new hole 47 is formed, called a lined hole, comprising a new bottom surface 43. The lined hole 47 and the new bottom surface 43 of the hole do not reproduce the defects present at the bottom of the initial hole 7.

Preferably, the depositing of the treatment layer 41 is anisotropic. It then has a topology which approximately reproduces a surface topology of the substrate 1 and of the initial hole 7. The thickness e of the treatment layer 41 is substantially identical on top of the main surface 10 and in the initial hole 7, i.e. between the bottom of the initial hole 7 and the new bottom surface 43 of the hole. On the other hand, the treatment layer 41 has a narrow thickness on the sidewalls of the initial hole 7 proportional to the thickness e of the treatment layer 41 on top of the main surface 10 or in the bottom of the initial hole 7. In this manner, the lined hole 47 substantially reproduces the topology and shape look of the initial hole 7. The treatment layer 41 is preferably deposited at low temperature, for example at a temperature of between about 300° C. and about 700° C. Persons skilled in the art know how to form a silicon layer on a silicon substrate in substantially anisotropic manner. Silicon is deposited on all the surfaces, but the lower the deposit temperature, the closer the morphology of the lined hole 47 with that of the initial hole 7. Conversely, the higher the temperature the more the material will be deposited at the bottom of the initial hole 7 leading to a more gentle hole topology.

The island 2 in the second material is then deposited in the lined hole 47 (FIG. 4C). In the remainder of the description, the term <<hole 7>> will indifferently relate to the initial holes 7 or the lined holes 47 unless they are explicitly referred to as the initial holes 7 or lined hole 47.

One example of the forming of islands in SiGe is described in the document <<Morphological evolution and lateral ordering of uniform SiGe/Si(001) islands>> by M Stoffel et al. published in the Microelectronics Journal, n° 37 (2006) pages 1528 to 1531, in 2006. In particular, paragraph 2 titled <<Experimental Procedure>> details a method for fabricating SiGe islands. In this example, a treatment layer in silicon is prepared by depositing silicon at between 480° C. and 700° C. or between 370° C. and 500° C. Germanium monolayers are then deposited by molecular beam epitaxy at temperature of between about 620° C. and 750° C. Cooling is then conducted e.g. at the rate of 1° C./s. The treatment layer used in the method described in this document is deposited in substantially isotropic manner. In general, the depositing of germanium monolayers is conducted at temperatures of between about 250° C. and 800° C. and at a pressure close to ultra-high vacuum for depositing via molecular beam epitaxy, or a few hectopascals for chemical vapour deposition.

The growth of the treatment layer 41 in silicon can be preceded by a step to remove any native oxide which may be formed during or in between some of the preceding steps. This step may comprise cleaning of RCA-clean type in three steps, comprising oxidation in a basic medium, oxidation in an acid medium and deoxidation. Alternatively, this step may comprise a cleaning in a hydrofluoric acid bath (HF) and/or hydrogen desorption.

One example of a method allowing islands in SiGe to be formed on a silicon substrate and to align a drain and source with these islands to form a transistor, is described in patent U.S. Pat. No. 6,872,625. In this document, the SiGe islands are formed directly above hollows present in the silicon substrate.

In the invention, the islands 2 do not need to be doped to obtain functional transistors. However those skilled in the art may wish to dope the SiGe islands 2 whilst remaining within the invention.

To prevent oxidation of the surface of the SiGe island further to exposure to air, it is preferable to form a capping layer 48 of silicon on the substrate 1 after forming the germanium island 2. This can be obtained using molecular beam epitaxy for example. The capping layer 48 advantageously has a thickness of a few nanometres e.g. between 1 nm and 50 nm, preferably between 2 and 5 nm. The SiGe island is then encased in silicon.

To form the capping layer 48, depositing may be conducted at a temperature of between about 50° C. and 600° C. depending on the expected planarity of the said capping layer.

As set forth in the two aforementioned documents, the islands 2 may be of different shapes in relation to the depositing conditions of the monolayers. Since the germanium island becomes Si₁₋ₓGeₓ via diffusion, its shape is more precisely related to the ratio of germanium and silicon in the island 2 or, in other words to the germanium content thereof. It is also estimated that the shape of the hole 7 also has an influence on the shape of the island 2.

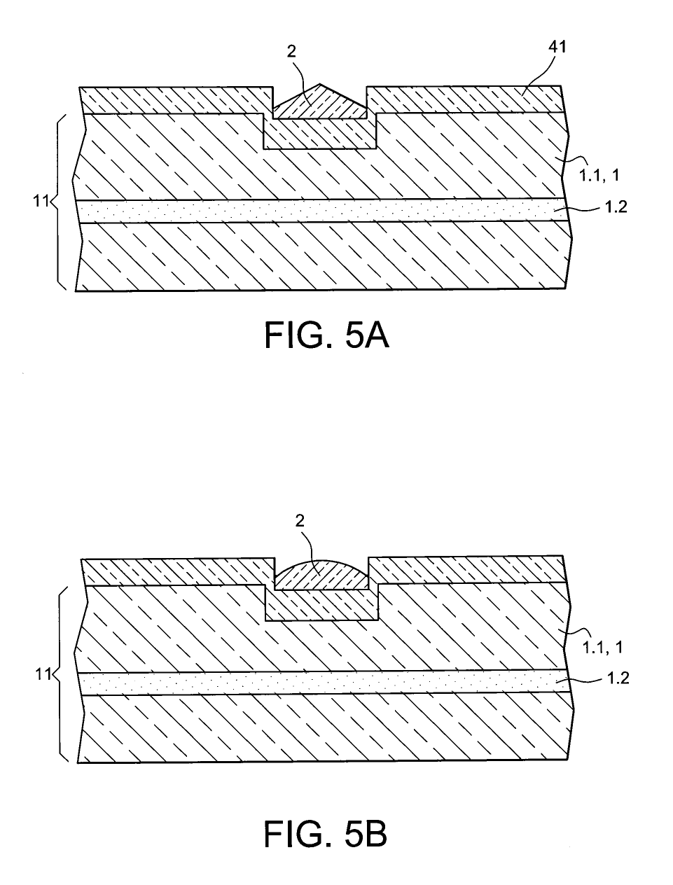

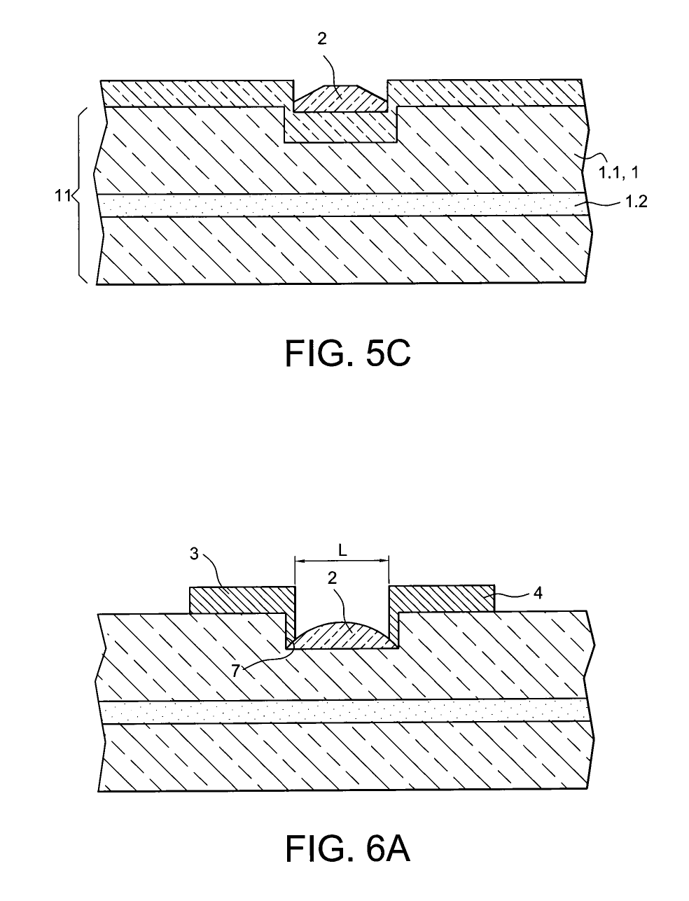

Different shapes of islands 2 are illustrated in FIGS. 5A to 5C.

These illustrate a pyramid shape (FIG. 5A), a dome or pseudo-dome shape (FIG. 5B). The so-called barn shape is roughly similar to the schematic in FIG. 5B, whilst the so-called but cluster shape is shown in FIG. 5C. It can further be envisaged to form island 2 in <<super-dome>> shape.

The obtaining of one or other of the shapes of the islands 2 can easily be controlled by those skilled in the art, after a few tests. Since the different possible shapes for the islands 2 are related to the germanium composition, they have an influence on different properties of the islands 2. However, the invention can be implemented using any shape of island 2.

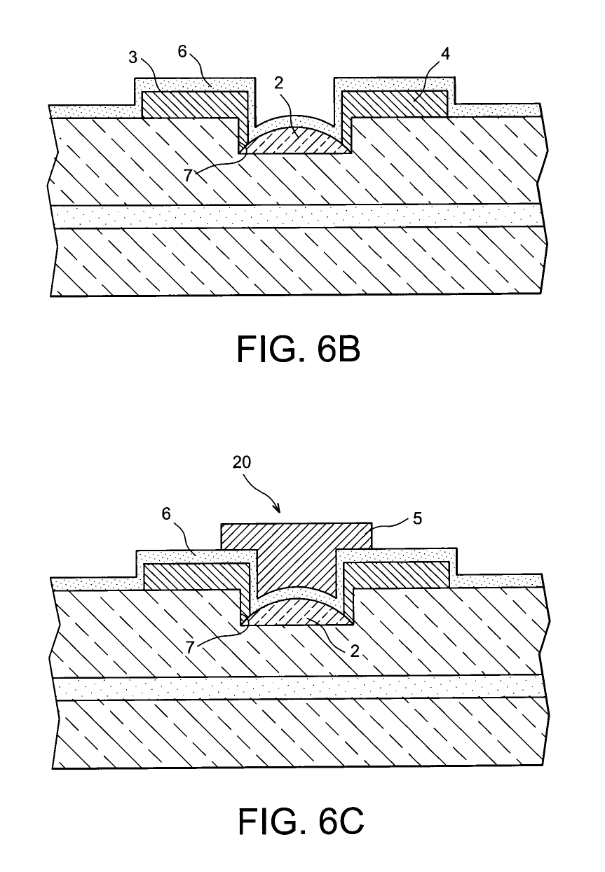

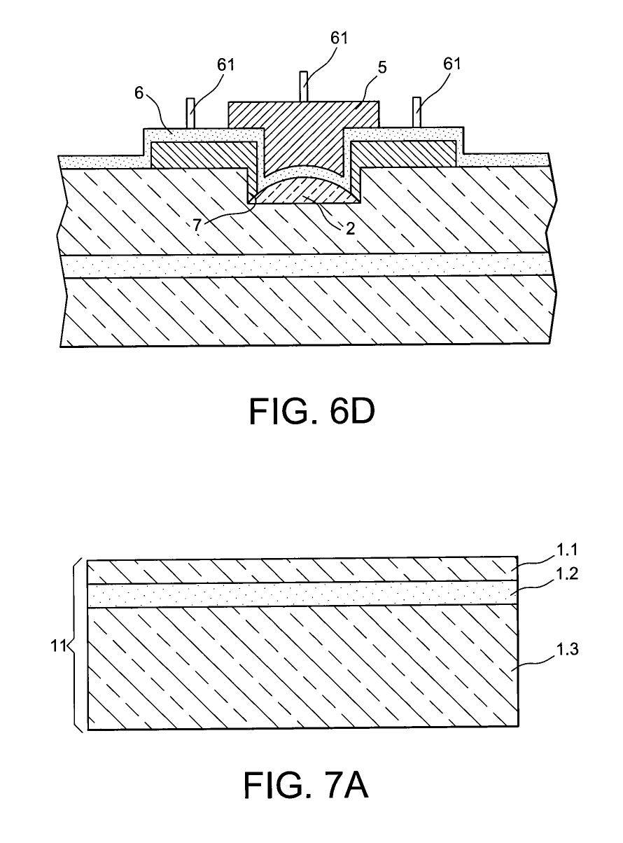

After forming the islands 2, one or more transistors are formed each having a channel region formed by one of the islands 2. Said method is outlined in FIGS. 6A to 6D for a single transistor on a single island 2.

The substrate 1 comprises an island 2 in SiGe in a hole 7 (FIG. 6A). On top of the island 2 two electrodes 3 and 4 are formed i.e. a source electrode 3 and a drain electrode 4. The two electrodes 3, 4 are each in direct electrical contact with the island 2 but are not in electrical contact with each other. They may be in any conductive material used in microelectronics such as mentioned above in the description of the transistor. Advantageously, the electrodes 3, 4 are in aluminium. In the remainder of the description, and for reasons of simplicity, it will be considered that the two electrodes 3, 4 are in aluminium although the invention concerns other types of conductive materials. In the example shown in FIG. 6A, the electrodes 3, 4 extend over the main surface 10 of the substrate 1 and over at least part of the sidewalls of the hole 7 and reach part of the island 2. However, the electrodes 3, 4 may be separated from the main surface 10 of the substrate 1 by an insulating layer, not illustrated, provided that the said insulating layer does not electrically separate the electrodes 3, 4 from the island.

The two electrodes 3, 4 may be produced by depositing aluminium through a resin mask obtained by lithography. Alternatively, they may be fabricated by depositing a layer of aluminium on the surface of the substrate followed by etching of the aluminium at every point where no electrodes are desired. The two electrodes 3, 4 are each at least partly in electrical contact with the island; they may therefore have parts which are not directly located above the island 2. One of the two electrodes 3, 4 may be located on the periphery of the island 2. However, alternatively, at least one of the two electrodes 3, 4 may cover a large portion of the island 2. At all events, a distance L between the two electrodes 3, 4 will define a gate length of the transistor.

Preferably, before depositing the conductive material intended for the formation of two electrodes 3, 4, the substrate 1 and the island 2 are subjected to HF cleaning. That is to say that the substrate 1 is dipped in a solution of hydrofluoric acid to remove any residual surface oxide which may be present on the surface of the island 2 and of the substrate 1.

Next, an insulating layer 6 is deposited on top of the substrate assembly 1 (FIG. 6B). It will therefore be understood that the insulating layer 6 is deposited on top of the two electrodes 3, 4, on top of every surface of the island 2 not covered by the two electrodes 3, 4 and on the main surface 10 of the substrate 1.

This insulating layer 6 is used to form a gate oxide for the transistor. It is preferably in silicon or hafnium oxide, but may be in any oxide used in microelectronics as gate oxide. Preferably, oxides are chosen that can easily be deposited by atomic layer deposition (ALD). For example, it is possible to use aluminium or zirconium oxides.

A second layer of semiconductor material is then deposited to form a gate 5 above the island 2, between the two electrodes 3, 4 (FIG. 6C). The gate 5 may be in any of the conductive materials usually used in microelectronics. It may in particular be in tungsten, aluminium or polysilicon.

In the same manner as for the two electrodes 3, 4, the gate 5 may be formed either by depositing conductive material through the mask, or by forming a layer of conductive material followed by etching of the said layer at the points where it is not desired to form a gate. Care is taken to ensure that every point of the island 2 located between the two electrodes 3, 4 is covered by the gate 5, separated therefrom by the insulating layer 6. Care must also be taken to ensure that the gate 5, at every point, is separated from the two electrodes 3, 4 by the insulating layer 6.

A transistor 20 is thereby formed.

The insulating layer 6 may then be removed at every point of the substrate 1 except at the points where the insulating layer 6 directly covers the island 2 and where the insulating layer 6 is directly covered by the gate 5. For example, the insulating layer 6 may be present solely directly above the island 2 covering it directly, or the insulating layer 6 may also completely cover the electrodes 3, 4 and lie directly above every point of the island 2. Any variation between these two cases is also possible.

As illustrated in FIG. 6D, the source electrode 3, drain electrode 4 and the gate 5 are then connected by electric connections 61 to an electronic circuit, not illustrated, which may comprise other transistors.

In one particular embodiment illustrated in FIG. 2, two neighbouring transistors 20 can be separated by trenches 21.

The trenches can be obtained by creating a mask by lithography, said mask being open at every part of the surface layer 1.1 to be removed. The mask protects at least the transistors during etching, optionally with a safety margin. This step can be performed after forming the gate or directly after forming the electrodes 3, 4.

With the invention it is therefore possible to produce transistors, whether isolated or included in a device. These transistors have the advantage of not requiring any doping step during their fabrication. In addition, these transistors do not require any dopant atoms to operate. As a result, the problems which arise with small-size transistors known in the prior art have a much reduced and even no influence on the transistors of the invention.

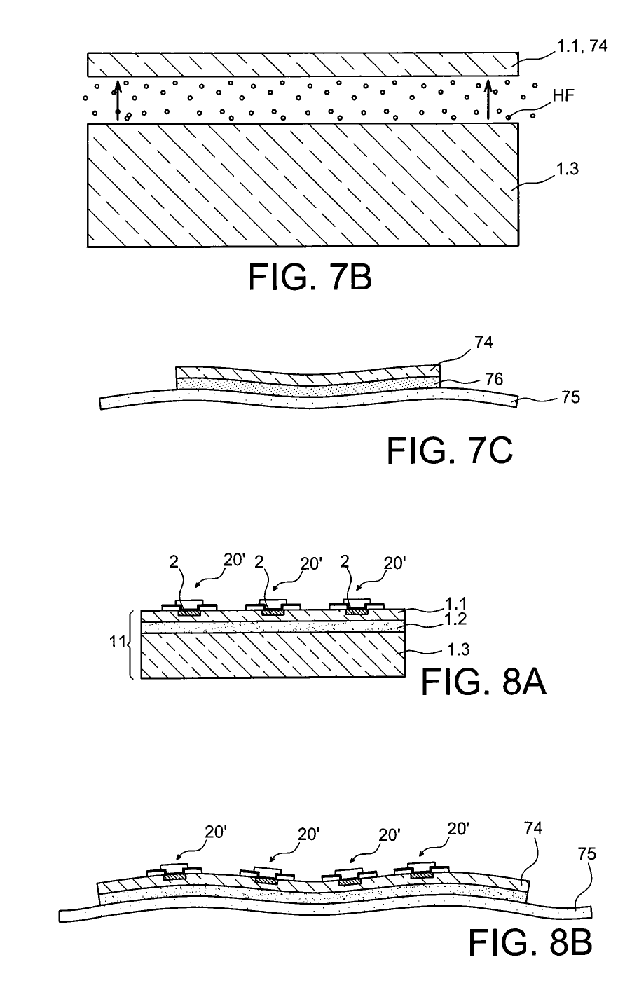

A substrate 11 of semiconductor-on-insulator type (SOI) comprises an upper layer in semiconductor material 1.1, fixed to a lower layer 1.3 of greater thickness, by an oxide layer 1.2 (FIG. 7A). If such substrate 11 having an upper layer 1.1 in semiconductor material of high quality is provided, it is possible to obtain a floating substrate 74 from the upper layer 1.1 (FIG. 7B). It is effectively easy to release the upper layer 1.1 from the lower layer 1.3 by chemically attacking the oxide layer connecting them together, for example using a hydrofluoric acid solution, HF.

If the floating substrate 74 obtained is very thin, it is possible to transpose it onto a flexible substrate 75 (FIG. 7C) by a bonding layer 76. A flexible substrate may be a substrate in polymer. By flexible substrate in the world of advanced microelectronics is meant a substrate which, if it is laid on a non-planar support, can roughly follow the topology of said support. It is a substrate which is neither globally crystalline nor an oxide or nitride. In general, it is polymer substrate. In the remainder hereof, it will be considered that a flexible substrate designates a polymer substrate without being limited thereto.

With the method of the invention it is possible to fabricate transistors 20, 20′ on very thin semiconductor layers (FIG. 8A). In particular, it is possible to use substrates 11 of SOI type whose upper layer 1.1 has a thickness of about 10 nm, 5 nm or even 2 nm. This is because, according to the invention, it is only needed to form holes in the substrate, for example to a depth of about 1 nm or 2 nm and to deposit a treatment layer a few nanometres thick. Next, the islands 2 are formed locally in the holes and there is absolutely no need to create a source or drain having a depth of several nanometres.

The method of the invention therefore opens up two possibilities.

The first possibility is to fabricate the transistors 20, 20′ according to the invention on a substrate 11 of SOI type (FIG. 8A), prior to transfer of the upper layer 1.1 onto a flexible substrate 75 (FIG. 8B). It is therefore possible initially to use substrates 11 of semiconductor-on-insulator type comprising a surface layer 1.1 in very thin semiconductor that is lifted off from the substrate 11 of SOI type after forming the 20, 20′ and a network of interconnects above the transistors.

This gives a very thin floating substrate 74 comprising transistors. The narrow thickness of the floating substrate 74 means that it is easily able to follow the contour shape of the flexible substrate 75 and any deformations of the said flexible substrate 75 allowing easy adhesive bonding thereof.

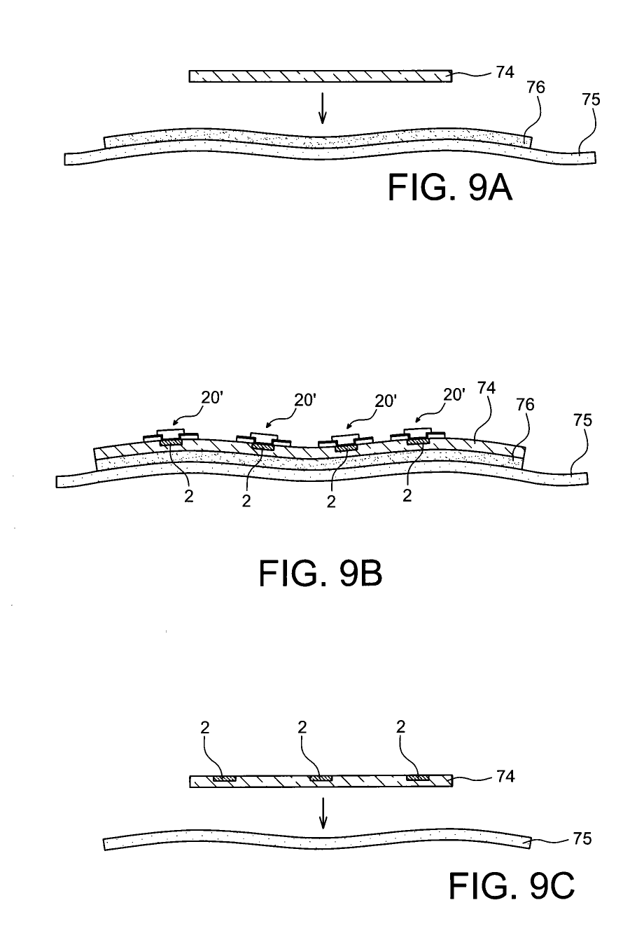

The second possibility is that of fabricating transistors according to the invention after the transfer of the upper layer onto the said flexible substrate. To bond a floating substrate 74 onto a flexible substrate 75, generally a polymer-based adhesive 76 is used (FIG. 9A). Said material degrades easily at high temperature, separating the floating substrate 74 from the flexible substrate 75. It is therefore generally not possible to conduct fabrication steps having a temperature higher than a critical temperature particular to the material of the adhesive 76. The annealing operations used to produce transistors using prior art silicon technology have recourse to temperatures incompatible with the said adhesives 76.

However, a method according to the method only uses steps at a temperature lower than about 180° C. Since there is no need to carry out the implanting of dopants or to perform diffusion annealing of the said dopants, the steps having a high heat budget are not necessary to fabricate transistors according to the invention. Therefore neither the adhesive 76 not the flexible substrate 75 risks being deteriorated during fabrication of the transistors.

Advantageously a method according to the invention (FIGS. 6A to 6D) will be used to form transistors 20, 20′ using silicon technology, on islands 2 present on top of a flexible substrate 75 without deteriorating this substrate (FIG. 9B).

The forming of the islands 2 is preferably performed before the release of the upper layer 1.1 of the substrate 11 of SOI type illustrated in FIG. 7B. A floating substrate 74 is thus obtained comprising islands 2 according to the invention (FIG. 9 C).

From the islands 2, transistors 20, 20′ can be fabricated according to the invention on a floating substrate 74 bonded onto a flexible substrate 75.

Thereafter it is possible to fabricate a network of interconnects above the transistors 20, 20′ so as to form a functional electronic circuit on the flexible substrate 75.

Interconnects can be obtained by atomic layer deposition or any other type of compatible method not requiring a temperature higher than the lift-off temperature.

1-16. (canceled)

17. A device comprising:
at least one transistor on a substrate in a first semiconductor material, each transistor comprising a gate electrode, as a gate, two metal electrodes, an island in a second semiconductor material inlaid in the substrate, defining a region capable of forming a channel as a channel region, and an insulating layer separating the gate from the two electrodes and from the channel region;
wherein the channel region lies inside the island and is in direct electrical contact with at least one of the two metal electrodes, the electrode lying partly above the island.

18. The device according to claim 17, wherein the channel region is in direct electrical contact on one side with one of the two metal electrodes, as a source electrode, and on the other side is in direct electrical contact with the other of the two conductor electrodes, as a drain electrode, the two metal electrodes being separated from each other by the gate.

19. The device according to claim 17, wherein the metal electrodes are in a metal chosen from among aluminium, copper, titanium, tungsten, gold, platinum.

20. The device according to claim 17, wherein the first semiconductor material is silicon and the second semiconductor material is Si₁₋ₓGeₓ, x being between 0 and 1.

21. The device according to claim 17, wherein the island has a height measured in a direction perpendicular to a main surface of the substrate, of between 1 nm and 60 nm.

22. The device according to claim 17, wherein the island has a width, measured in a plane parallel to a main surface of the substrate, of between 10 nm and 400 nm.

23. The device according to claim 17, wherein the substrate is of semiconductor-on-insulator type (SOI).

24. The device according to claim 17, comprising plural transistors, wherein a trench in the substrate electrically insulates at least two of the plural transistors.

25. The device according to claim 17, wherein the substrate is an upper layer in semiconductor material of thickness of about 10 nm or less, present on a flexible substrate.

26. A method for fabricating a device having at least one transistor, comprising:
a) forming one or more holes having a given depth and width hollowed in a surface of a substrate in a first semiconductor material;
b) forming an island in a second semiconductor material in each hole;
c) on each island forming at least a first metal electrode extending partly above each island in direct electrical contact with the island;
d) forming at least one second metal electrode per island whether or not in direct electrical contact with the island;
e) depositing an electrically insulating layer on the surface of the substrate, above each island and each metal electrode;
f) depositing a metal layer above the island, separated from the island and the metal electrodes by the insulating layer, and forming a gate electrode.

27. The method according to claim 26, wherein the second electrode is in direct electrical contact with the island.

28. The method according to claim 26, wherein the b) forming is preceded by anisotropic deposition of a layer of single-crystal silicon, as a treatment layer, the holes made at the a) forming creating a given topology; the treatment layer lines the holes and creates a new surface having substantially a same topology as that created at the a) forming and comprising lined holes.

29. The method according to claim 26, wherein the b) forming comprises depositing of germanium monolayers in the holes, forming a germanium island in each hole, and simultaneous diffusion of silicon in the germanium island.

30. The method according to claim 29, wherein the b) forming is followed by depositing of a capping layer in single-crystal silicon covering at least the germanium island.

31. The method according to claim 26, wherein a trench is formed between at least two neighbouring transistors, so as partly to insulate the two neighbouring transistors, the trench being devoid of solid material or filled with an insulating material.

32. The method according to claim 26, wherein the substrate is a surface layer, comprising the main surface in which the holes are hollowed, of a substrate of semiconductor-on-insulator type (SOI), the surface layer being separated from the substrate of SOI type and bonded onto a flexible polymer substrate, prior to a) or c) or after forming the transistors.
